(19) United States
(12) Patent Application Publication
(10) Pub. No.: US 2026/0016794 A1
(43) Pub. Date: Jan. 15, 2026

(54) RECORDING MEDIUM, INFORMATION PROCESSING APPARATUS, AND INFORMATION PROCESSING METHOD

(71) Applicant: Tokyo Electron Limited, Tokyo (JP)

(72) Inventor: Hirokazu KYOKANE, Nirasaki City (JP)

(21) Appl. No.: 19/283,819

(22) Filed: Jul. 29, 2025

Related U.S. Application Data
(63) Continuation of application No. PCT/JP2024/000979, filed on Jan. 16, 2024.

(30) Foreign Application Priority Data
Jan. 30, 2023 (JP) 2023-012154

(51) Int. Cl. G05B 13/02; G05B 13/04

(52) U.S. Cl. CPC G05B 13/0265; G05B 13/042

(57) ABSTRACT

A non-transitory computer-readable recording medium stores a computer program that causes a computer to perform: acquiring a first model that simulates a behavior of a first substrate processing; setting a range of variables that are able to approximate the acquired first model by a regression equation; deriving a regression equation that approximates the first model within the set range; acquiring observation data on a second substrate processing different from the first substrate processing; and generating a second model that simulates a behavior of the second substrate processing by adjusting coefficients of the regression equation based on the acquired observation data.

### CROSS-REFERENCE TO RELATED APPLICATIONS

This application is a bypass continuation application of International Patent Application No. PCT/JP2024/000979 having an international filing date of Jan. 16, 2024 and designating the United States, the international application being based upon and claiming the benefit of priority from Japanese Patent Application No. 2023-012154, filed on Jan. 30, 2023, the entire contents of which are incorporated herein by reference.

### TECHNICAL FIELD

The present disclosure relates to a recording medium, an information processing apparatus, and an information processing method.

### BACKGROUND

When performing a process of a substrate processing, searching for process conditions that are capable of achieving a target process result is performed. For example, Patent Document 1 discloses a method of searching for process conditions by using a machine learning model. In Patent Document 1, a process condition is selected by selecting a machine learning model suitable for a data set, performing an optimization calculation by using the selected machine learning model, and calculating a prediction value of a process result and reliability of the prediction value with respect to a plurality of process conditions.

### PRIOR ART DOCUMENTS

### Patent Documents

Patent Document 1: Japanese Laid-Open Publication No. 2022-119321

### SUMMARY

According to one embodiment of the present disclosure, there is provided a non-transitory computer-readable recording medium storing a computer program that causes a computer to perform: acquiring a first model that simulates a behavior of a first substrate processing; setting a range of variables that are able to approximate the acquired first model by a regression equation; deriving a regression equation that approximates the first model within the set range; acquiring observation data on a second substrate processing different from the first substrate processing; and generating a second model that simulates a behavior of the second substrate processing by adjusting coefficients in the regression equation based on the acquired observation data.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram illustrating a processing overview in an embodiment.

FIG. 2 is a block diagram illustrating an internal configuration of an information processing apparatus.

FIG. 3 is an explanatory diagram illustrating an experimental result in a second substrate processing apparatus.

FIG. 4 is an explanatory diagram illustrating an introduction method of a regression equation.

FIG. 5 is an explanatory diagram illustrating an outline of an operation expression.

FIG. 6 is a flowchart illustrating a procedure of a processing performed by the information processing apparatus.

FIG. 7 is a schematic diagram illustrating an example of a user interface provided by the information processing apparatus.

FIG. 8 is a schematic diagram illustrating a schematic configuration of a vertical furnace including a plurality of zones.

FIG. 9 is a schematic diagram illustrating a schematic configuration of a single-wafer type apparatus.

FIG. 10 is a schematic diagram illustrating an analysis result of a trend analysis.

FIG. 11 is an explanatory diagram illustrating an outline of optimization.

FIG. 12 is a graph illustrating an example of a verification result.

FIG. 13 is an explanatory diagram illustrating a search method of a machine specification.

FIG. 14 is an explanatory diagram illustrating a search method of an operation condition.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments are described with reference to the drawings.

### Embodiment 1

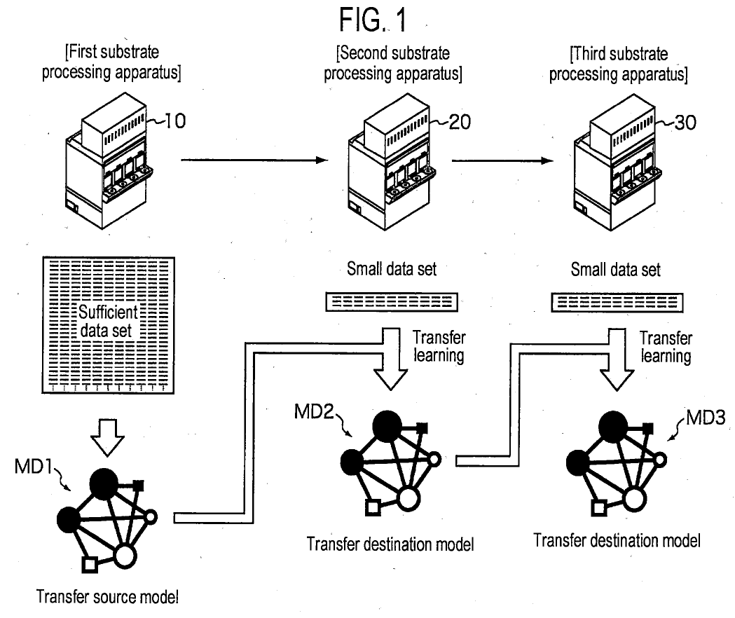

FIG. 1 is an explanatory diagram illustrating a processing overview in an embodiment. In the embodiment, a first substrate processing apparatus 10 is a representative apparatus that becomes a base. The first substrate processing apparatus 10 is a substrate processing apparatus such as an exposure apparatus, an etching apparatus, a film forming apparatus, an ion implantation apparatus, an ashing apparatus or a sputtering apparatus, and performs an appropriate substrate processing. The first substrate processing apparatus 10 may be a batch type apparatus that integrally processes a plurality of substrates and may be a single-wafer type apparatus that processes a plurality substrates one by one. Further, the first substrate processing apparatus 10 may be a substrate processing system composed of a plurality of substrate processing apparatuses.

In the embodiment, in relation to the first substrate processing apparatus 10, a model (first model MD1) that simulates a behavior of a substrate processing (first substrate processing) performed inside the apparatus is generated.

As the first model MD1, an arbitrary model that represents a relationship between input data (explanatory variables) and output data (object variables) is used. The input data are, for example, data such as a heater temperature, a gas flow rate, and a pressure, and the output data are, for example, data such as a film thickness, a film forming speed, an in-plane uniformity, and an inter-plane uniformity. These data are observation data gathered using appropriate sensors. As the model, for example, a machine learning model such as a regression model, a moving average model, a decision tree, a support vector machine or a neural network is used. Alternatively, as for the model, a mathematical model based on a statistical model or a physical theory may be used. A model used as the first model MD1 is appropriately selected according to a combination of the explanatory variables and the object variables, and is generated according to the selected model by using an existing method.

Precision and versatility may be required in models. Therefore, when the first model MD1 is generated based on an experimental result, an experiment (the first substrate processing) is repeatedly performed in the first substrate processing apparatus 10, so that a data set including a plurality of observation data is prepared in advance. The first model MD1 is generated using the prepared sufficient data set. Accordingly, precision and versatility of the first model MD1 are ensured.

A second substrate processing apparatus 20 or a third substrate processing apparatus 30 is an apparatus newly introduced to development fields or mass production fields. The second substrate processing apparatus 20 is an apparatus (same apparatus) that performs the same process as the first substrate processing apparatus 10, an apparatus (similar apparatus) that performs a process similar to that of the first substrate processing apparatus 10, or the like. The second substrate processing apparatus 20 may be a remodeled apparatus obtained by remodeling the first substrate processing apparatus 10, or may perform a new processing by using the first substrate processing apparatus 10 as it is. The third substrate processing apparatus 30 is the same as above. In FIG. 1, only the second substrate processing apparatus 20 and the third substrate processing apparatus 30 are shown as substrate processing apparatuses introduced to development fields or mass production fields, but a larger number of substrate processing apparatuses may be introduced to the development fields or mass production fields.

In general, since a machine difference between apparatuses exists, a model applied to each apparatus is individually generated for each apparatus. Conventionally, in order to generate a model applied to each apparatus, an experiment is repeatedly performed in each apparatus, so that a data set including a plurality of observation data is prepared for each apparatus. Further, it is known that the number of experiments required to generate a model increases exponentially with the number of variables included in the model. Therefore, in order to generate a model for each apparatus, conventionally, a lot of experiments are needed to be performed, and hence an experimental load or a cost tends to increase.

In contrast, in the embodiment, a model applied to the second substrate processing apparatus 20 or the third substrate processing apparatus 30 is generated using a small data set obtained from several experiments. Specifically, an elaborate and detailed model is generated with respect to the representative apparatus that becomes the base, and models (a second model MD2 and a third model MD3) applicable to the second substrate processing apparatus 20 and the third substrate processing apparatus 30 in transfer destinations are generated by transfer learning of the model. In the embodiment, a model applicable to each apparatus is generated by using a small data set obtained from several experiments, and thus an increase in the experimental load or the cost is suppressed.

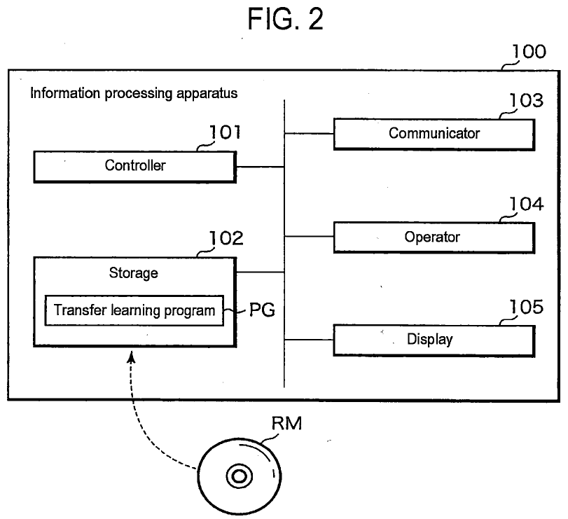

Hereinafter, a method of generating the second model MD2 applied to the second substrate processing apparatus 20 is mainly described. An information processing apparatus 100 (see FIG. 2) is used for generating the second model MD2. Further, for generating the first model MD1 or the third model MD3, the same information processing apparatus 100 may be used or different information processing apparatuses may be used.

FIG. 2 is a block diagram illustrating an internal configuration of the information processing apparatus 100. The information processing apparatus 100 is a dedicated or general-purpose computer, and includes a controller 101, a storage 102, a communicator 103, an operator 104, a display 105, and the like.

The controller 101 includes a central processing unit (CPU), a read only memory (ROM), a random access memory (RAM), and the like. The ROM provided in the controller 101 stores control programs and the like, which control an operation of each component of hardware included in the information processing apparatus 100. The CPU in the controller 101 reads and executes the control programs stored in the ROM or computer programs stored in the storage 102, and controls the operation of each component of the hardware, thus causing the entire apparatus to function as the information processing apparatus 100 of the present disclosure. The RAM provided in the controller 101 temporarily stores data used during execution of an arithmetic operation.

In the embodiment, although the controller 101 includes the CPU, the ROM, and the RAM, the configuration of the controller 101 is not limited to the above-described configuration. The controller 101 may be, for example, one or more control circuits or operation circuits, which include a graphics processing unit (GPU), a field programmable gate array (FPGA), a digital signal processor (DSP), a quantum processor, a volatile or nonvolatile memory, or the like. Further, the controller 101 may include functions such as a clock for outputting temporary information, a timer for measuring a time elapsed from a time when a measurement start instruction is given to a time when a measurement end instruction is given, and a counter for counting a number.

The storage 102 includes computer readable storage devices such as a hard disk drive (HDD), a solid state drive (SSD), and an electronically erasable programmable read only memory (EEPROM). The storage 102 stores various types of computer programs executed by the controller 101 or various data used by the controller 101.

The computer programs stored in the storage 102 include a transfer learning program PG for causing the computer to perform a processing for generating the second model MD2. The computer programs including the transfer learning program PG may be provided by a non-transitory recording medium RM that readably stores the computer programs. The recording medium RM is, for example, a portable recording medium such as a secure digital (SD) card, a micro SD card or a compact flash (trademark). The controller 101 reads computer programs from the recording medium RM by using a reader (not illustrated) and stores the read computer programs in the storage 102. Further, the computer programs including the transfer learning program PG may be provided by communication. In this case, the controller 101 acquires computer programs by the communication via the communicator 103, and stores the acquired computer programs in the storage 102.

The communicator 103 includes a communication interface for transmitting/receiving various data to/from an external apparatus including the second substrate processing apparatus 20. As the communication interface included in the communicator 103, for example, a communication interface conforming to a communication standard such as a local area network (LAN) may be used. When data to be transmitted is input from the controller 101, the communicator 103 transmits the data to an external apparatus of a receiving destination. When data transmitted from an external apparatus is received, the communicator 103 outputs the received data to the controller 101.

The operator 104 includes operating devices such as a touch panel, a keyboard, and switches, and receives various types of operations and settings by a manager or the like. The controller 101 performs appropriate controls based on various operation information given from the operator 104, and causes the storage 102 to store information input from the operator 104 as necessary.

The display 105 includes a display device such as a liquid crystal monitor or an organic electro-luminescence (EL), and displays information to be notified to the manager or the like in response to an instruction from the controller 101.

The information processing apparatus 100 may be a single computer or may be a computer system composed of a plurality of servers, surrounding devices, or the like. Further, the information processing apparatus 100 may be a virtual machine in which entities are virtualized, or may be a cloud.

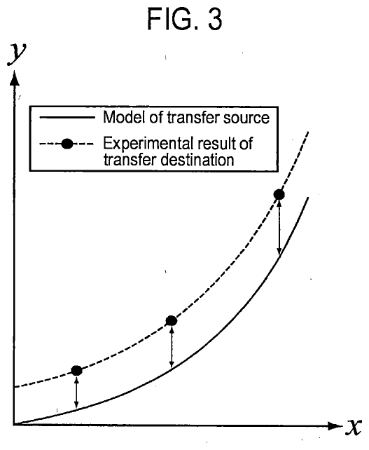

FIG. 3 is an explanatory diagram illustrating an experimental result in the second substrate processing apparatus 20. It is assumed that the first model MD1 of a transfer source is generated in advance before an experiment in the second substrate processing apparatus 20 as a transfer destination. The first model MD1 is an elaborate and detailed machine learning model or statistic model learned using a sufficient data set. Alternatively, the first model MD1 may be a mathematical model based on a physical theory. In the first model MD1, when focusing on one explanatory variable x and plotting a change of an object variable y with respect to the explanatory variable x, for example, a graph illustrated in FIG. 3 is obtained. In the graph shown in FIG. 3, the horizontal axis represents the explanatory variable x in focus, and the vertical axis represent the object variable y. The change of the object variable y with respect to the explanatory variable x is indicated by a solid line.

Meanwhile, it is assumed that as a result obtained by performing an experiment (second substrate processing) in the second substrate processing apparatus 20, observation data indicated by black circles in the graph are obtained. A broken line appended as a reference virtually represents a behavior of the second substrate processing.

In general, since a machine difference between apparatuses exists, even if the first model MD1 derived from the first substrate processing apparatus 10 is used as it is, it is impossible to reproduce the experimental result in the second substrate processing apparatus 20 with high precision. FIG. 3 shows a state in which errors occur between the first model MD1 in the first substrate processing apparatus 10 and the experimental result in the second substrate processing apparatus 20.

Accordingly, in this embodiment, a regression equation is introduced to the first model MD1 and a method of adjusting coefficients (an intercept and a slope) in the regression equation is proposed in order to reproduce the experimental result of the second substrate processing apparatus 20 by using the introduced regression equation.

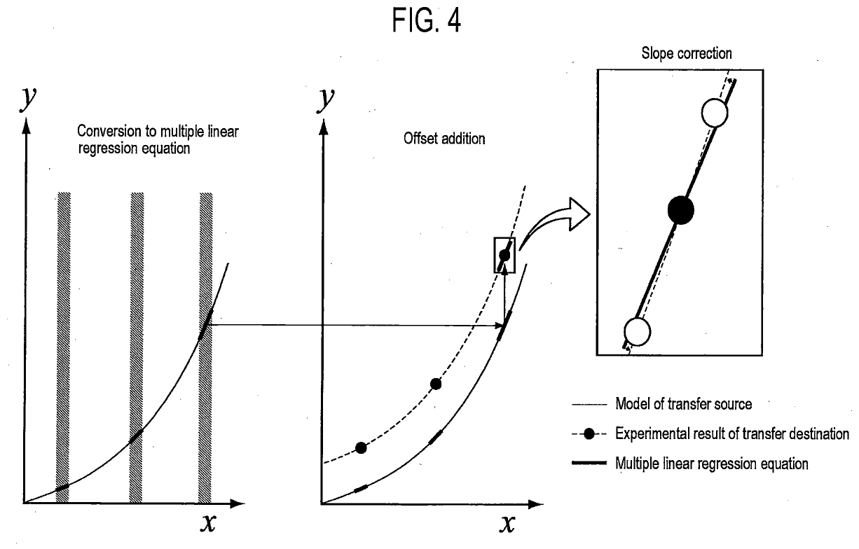

FIG. 4 is an explanatory diagram illustrating an introduction method of a regression equation. In the graph at a left end of FIG. 4, the first model MD1 of the transfer source is indicated by a fine line. In this embodiment, for the first model MD1, a range (process window) of variables that are able to be approximated by a regression equation is set. The process window is set, for example, by receiving a lower limit and an upper limit of the variables. The process window is shown as a hatched region in the graph at the left end of FIG. 4.

A regression equation that approximates the first model MD1 is derived within the set process window. In this embodiment, it is aimed to achieve transfer learning by a small number of experiments, and hence a regression equation that is able to be expressed with a linear combination is desirably used as the regression equation. In general, a model includes a plurality of explanatory variables, and hence a multiple linear regression equation is used as the regression equation that approximates the first model MD1. A multiple linear regression equation including n (n is an integer of 2 or more) explanatory variables is generally expressed as the following Equation 1.

$$y = ( \begin{matrix}{β}_{1} & {β}_{2} & {β}_{3} & … & {β}_{n} & {β}_{c o n s t}\end{matrix} ) ( \begin{matrix}{x}_{1} \\ {x}_{2} \\ {x}_{3} \\ ⋮ \\ {x}_{n} \\ 1\end{matrix} ) = {β}_{S} x \qquad [ Equation 1 ]$$

Here, y is an object variable, x₁, x₂, x₃, . . . , xₙ are explanatory variables, β₁, β₂, β₃, . . . , βₙ are partial regression coefficients, and β_{const} is an intercept.

For example, when the explanatory variables are set as a temperature (=xₜₑₘₚ), a mass flow rate (=x_{MF}), and a pressure (=xₚᵣₑₛₛ), the object variable y is expressed by a multiple linear regression equation of Equation 2. The object variable y is a film thickness, a film forming speed, an in-plane uniformity, an inter-plane uniformity or the like.

$$y = \begin{matrix}( {β}_{{S}_{t e m p}} & {β}_{{S}_{M F}} & {β}_{{S}_{ρ r e s s}} & {β}_{{S}_{c o n s t}} )\end{matrix} ( \begin{matrix}{x}_{t e m ρ} \\ {x}_{M F} \\ {x}_{p r e s s} \\ 1\end{matrix} ) = {β}_{S} x \qquad [ Equation 2 ]$$

Here, β_{Stemp}, β_{SMF}, and β_{Spress} are partial regression coefficients in the multiple linear regression equation. The partial regression coefficients are also referred to as a slope or a degree of contribution. β_{Sconst} is an intercept in the multiple linear regression equation. The multiple linear regression equation that approximates the first model MD1 is indicated by a thick line in the graph at the left end of FIG. 4.

In addition, when nonlinearity of the model is added, a linear region may be extended to a nonlinear region by putting square terms of the explanatory variables. When interaction between the explanatory variables is added, the linear region may be extended to the nonlinear region by putting an interaction term.

As described above, since a machine difference between apparatuses exists, it is impossible to reproduce the experimental result in the transfer destination with high precision even when the model derived from the transfer source is used as it is.

Accordingly, in this embodiment, in order to resolve an error between the model of the transfer source and the experimental result of the transfer destination, an offset is added to the approximated multiple linear regression equation. A graph shown at a center of FIG. 4 shows a state in which an offset is added to the multiple linear regression equation that approximates the first model MD1, thereby reproducing the experimental result in the second substrate processing apparatus 20.

The multiple linear regression equation to which the offset is added substantially reproduces the experimental result in the second substrate processing apparatus 20. However, as shown in a partial enlarged view of FIG. 4, the multiple linear regression equation (thick line) to which the offset is added has a slope slightly different from a slope in an actual behavior (broken line) of the second substrate processing. In this embodiment, the slope is corrected by referring to a small number of additional experiments, thus realizing a model that is capable of reproducing a predetermined process range. In the partial enlarged view of FIG. 4, white circles represent observation data of the second substrate processing apparatus 20, which are obtained by additional experiments.

When the above-described xₜₑₘₚ, x_{MF}, and xₚᵣₑₛₛ are used as the explanatory variables, the multiple linear regression equation that reproduces the observation data of the transfer destination (the second substrate processing apparatus 20) is expressed by Equation 3.

$$y = \begin{matrix}( {β}_{{T}_{t e m p}} & {β}_{{T}_{M F}} & {β}_{{T}_{p r e s s}} & {β}_{{T}_{c o n s t}} )\end{matrix} ( \begin{matrix}{x}_{temp} \\ {x}_{M F} \\ {x}_{p r e s s} \\ 1\end{matrix} ) = {β}_{T} x \qquad [ Equation 3 ]$$

Here, β_{Ttemp}, β_{TMF}, and β_{Tpress} are partial regression coefficients in the multiple linear regression equation. The partial regression coefficients are also referred to as a slope or a degree of contribution. β_{Tconst} is an intercept in the multiple linear regression equation.

In adjusting the coefficients (intercepts and slopes) in the above-described multiple linear regression equation, an operation expression of Equation 4 is used.

$${β}_{T} = arg min ( {\sum }_{i}^{n} {‖ {y}_{T} - {β}_{i} x ‖}^{2} + {λ}_{1} {‖ {β}_{i}^{′} - {β}_{s}^{′} ‖}^{2} + {λ}_{2} {\sum }_{j \neq i}^{n - 1} \frac{1}{{r}^{2}} {‖ {β}_{i}^{′} - {β}_{j}^{′} ‖}^{2} ) \qquad [ Equation 4 ]$$

Here, β_{T} in the left-hand side is a coefficient of the multiple linear regression equation that approximates the model (second model MD2) of the transfer destination. β_{T} includes an intercept and a slope. In the first term in the right-hand side, x is an explanatory variable in the transfer destination, y_{T} is an object variable in the transfer destination, and βᵢ is a coefficient in the multiple linear regression equation of the transfer destination. βᵢ includes an intercept and a slope. In the second term in the right-hand side, β′ᵢ is a coefficient in the multiple linear regression equation of the transfer destination, and β′_{S} is a coefficient in the multiple linear regression equation of the transfer source. β′ᵢ and β′_{S}, each having a single quotation mark attached thereto represent coefficients (i.e., only slopes) including no intercept. In the third term in the right-hand side, β′ᵢ and β′ⱼ are coefficients at two arbitrary points in a substrate plane. β′ᵢ and β′ⱼ, each having a single quotation mark attached thereto represent coefficients (i.e., only slopes) including no intercept. r is a distance between the two points. λ₁ and λ₂ are parameters for adjustment.

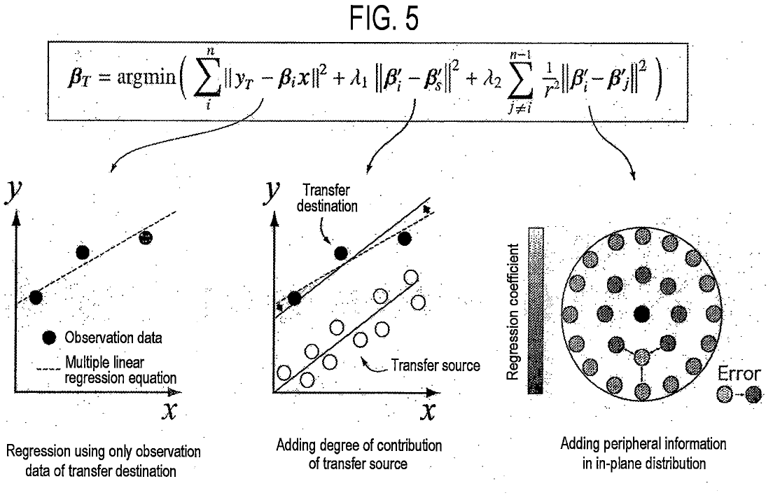

FIG. 5 is an explanatory diagram illustrating an outline of the operation expression. The first term in the right-hand side of Equation 4 represents a regression using only the observation data in the transfer destination. The coefficient βᵢ of the first term in the right-hand side includes an intercept and a slope, and hence the coefficient including the intercept is adjusted in this term. This term corresponds to adding an offset to the multiple linear regression equation of the transfer source so as to resolve the error between the model of the transfer source and the experimental result of the transfer destination.

The second term in the right-hand side of Equation 4 represents adding a degree of contribution of the transfer source. The second term in the right-hand side includes the coefficient β′ᵢ of the transfer destination and the coefficient β′_{S} of the transfer source, but no intercept is included in the coefficients β′ᵢ and β′_{S}. Therefore, a slope of the transfer destination is adjusted by adding the degree of contribution of the transfer source.

The first term and the second term in the right-hand side correspond to adjusting the coefficients (intercepts and slopes) in the multiple linear regression equation so as to reproduce the observation data of the transfer destination by imposing a penalty to the degree of contribution (slope) to become a value close to a value of the transfer source, without imposing any penalty to the intercept.

The third term in the right-hand side of Equation 4 means adjusting the coefficients by imposing a penalty according to the distance between the two points based on knowledge that an in-plane distribution of the degree of contribution (slope) does not suddenly change in a vicinity thereof. For example, when coefficients in adjacent regions within the substrate plane are considerably different, the coefficients are corrected by adding peripheral information.

λ₁ and λ₂ are parameters for adjustment, and have real numbers of 0 or more. A large value is set in λ when the degree of contribution of the transfer source is emphasized, and a small value is set in Mu when the regression at the transfer destination is emphasized. Further, when the in-plane distribution is not considered, the parameter λ₂ for adjustment may be set to zero.

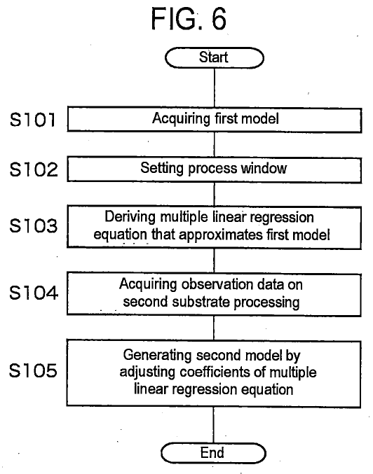

FIG. 6 is a flowchart illustrating a procedure of a processing performed by the information processing apparatus 100. The controller 101 of the information processing apparatus 100 acquires the first model MD1 (step S101). The first model MD1 is, for example, an elaborate and detailed model that simulates the behavior of the substrate processing (first substrate processing) in the first substrate processing apparatus 10. When the first model MD1 is generated in an external apparatus, the controller 101 acquires the first model MD1 from the external apparatus by accessing the external apparatus via the communicator 103. When the first model MD1 is generated inside the information processing apparatus 100 and stored in the storage 102, the controller 101 acquires the first model MD1 from the storage 102 by accessing the storage 102. In this embodiment, the first model MD1 is a model that becomes the transfer source in transfer learning.

The controller 101 sets a process window with respect to the first model MD1 (step S102). The controller 101 is able to set the process window by receiving a setting for an upper limit value and a lower limit value, which determines the process window, via the operator 104. A plurality of process windows may be set.

The controller 101 derives a multiple linear regression equation (y=β_{S}X) that approximates the first model MD1 within the set process window (step S103). The controller 101 may derive the multiple linear regression equation that approximates the first model MD1 by using an existing method such as a least squares method. In this step, a coefficient β_{S} in the multiple linear regression equation of the transfer source is obtained.

The controller 101 acquires observation data on the substrate processing (second substrate processing) performed in the second substrate processing apparatus 20 (step S104). The controller 101 acquires the observation data on the second substrate processing by accessing the second substrate processing apparatus 20 via the communicator 103. Herein, data corresponding to explanatory variables and object variables, which are obtained in several-time (two-to three-time) additional experiments, may be acquired.

The controller 101 adjusts the coefficients in the multiple linear regression equation based on the acquired observation data, thereby generating the second model MD2 that simulates the behavior of the second substrate processing (step S105). The controller 101 may generate a model that simulates the behavior of the second substrate processing within the set process window by calculating a coefficient β_{T} according to the operation expression of Equation 4. The controller 101 may generate a model that simulates the behavior of the second substrate processing within each process window by changing a range of the process window as necessary.

As described above, the second model MD2 may be generated by the transfer learning of the first model MD1. That is, in this embodiment, the second model MD2 that simulates a behavior of a substrate processing in another apparatus introduced to development fields or mass production fields may be generated based on the first model MD1 that simulates a substrate processing in the representative apparatus. In this embodiment, the second model MD2 is generated using the transfer learning based on a small data set obtained in several-time additional experiments, and thus it is possible to suppress an increase in experimental load or cost.

In addition, in this embodiment, a method of generating the second model MD2 by the transfer learning of the first model MD1 has been mainly described, but the third model MD3 and the like may be generated by the transfer learning of the second model MD2, using the same method.

### Embodiment 2

A user interface provided by the information processing apparatus 100 is described.

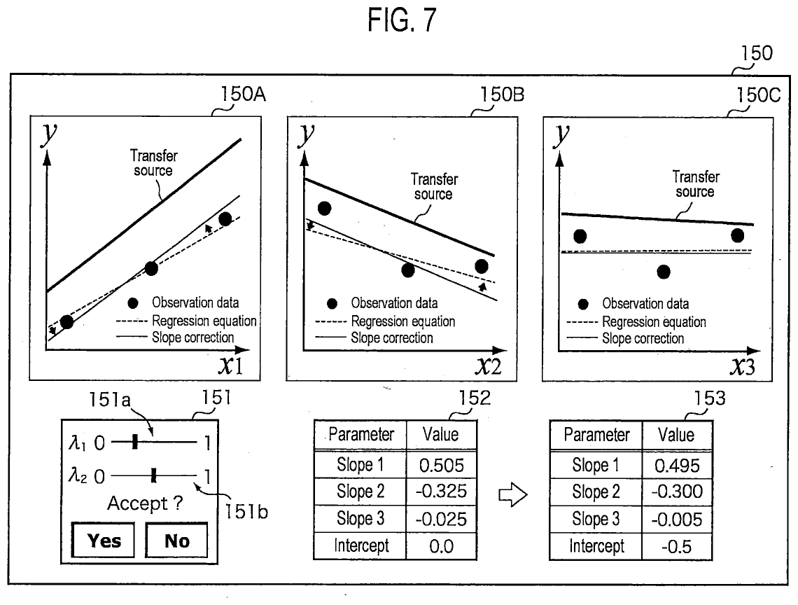

FIG. 7 is a schematic diagram illustrating an example of a user interface provided by the information processing apparatus 100. When performing a regression calculation of a transfer destination, the controller 101 of the information processing apparatus 100 causes an interface screen 150 as shown in FIG. 7 to be displayed on the display 105. The interface screen 150 includes, for example, graph display columns 150A to 150C that display regression equations as graphs, an adjustment column 151 that receives adjustment of parameters 21 and 22 for adjustment, and display columns 152 and 153 that display slopes and intercepts before and after the adjustments.

The graph display columns 150A to 150C display a regression equation obtained for a first substrate processing (transfer source), observation data of a second substrate processing (transfer destination), a regression equation that is calculated from the observation data, a regression equation after slope correction, and the like, corresponding to respective explanatory variables. x₁ to x₃ shown in the graphs correspond to, for example, explanatory variables xₜₑₘₚ, x_{MF}, and xₚᵣₑₛₛ.

The adjustment column 151 receives the adjustment of the parameters λ₁ and λ₂ for adjustment in the operation expression of Equation 4. The adjustment column 151 includes sliders 151a and 151b that change the parameters λ₁ and λ₂ for adjustment in a real number range of 0 to 1. When λ₁ and λ₂ are changed by the sliders 151a and 151b, the controller 101 re-calculates Equation 4 and reflects calculation results in real time on the graph display columns 150A to 150C.

Slopes and intercepts before the parameters λ₁ and λ₂ for adjustment are adjusted are displayed in the display column 152, and slopes and intercepts after the parameters λ₁ and λ₂ for adjustment are adjusted are displayed in the display column 153.

As described above, in Embodiment 2, when the parameters A and 22 for adjustment are changed, the calculation results of Equation 4 are reflected on the graph display columns 150A to 150C, and the slopes and intercepts before and after the adjustment are displayed in the display columns 152 and 153, so that a manager or the like is able to determine a second model MD2 in the transfer destination while checking the calculation results of the regression coefficients.

### Embodiment 3

Although a configuration in which a model is transferred between different apparatuses has been described in Embodiment 1, when a substrate processing apparatus is a vertical furnace including a plurality of zones, a configuration in which a model is transferred between the zones may be used.

In Embodiment 3, an application example to the vertical furnace is described.

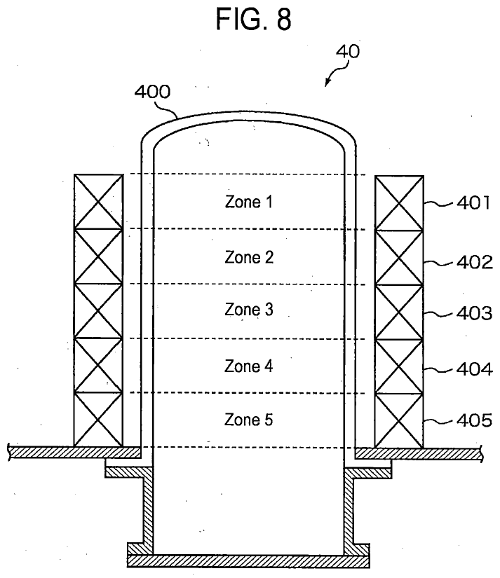

FIG. 8 is a schematic diagram illustrating a schematic configuration of a vertical furnace including a plurality of zones. A vertical furnace 40 shown in FIG. 8 is a chemical vapor deposition (CVD) apparatus, and includes a reaction tube 400 having a double tube structure and oxidation apparatuses 401 to 405. The vertical furnace 40 is of a batch type, and the reaction tube 400 is divided into five zones (zones 1 to 5). The oxidation apparatuses 401 to 405 are provided corresponding to the respective zones, and are configured to perform an oxidation processing at a time on substrates placed in the respective zones.

In Embodiment 3, an elaborate and detailed model (first model MD1) is generated in advance by using a sufficient data set prepared in a specific zone (e.g., the zone 3). The information processing apparatus 100 acquires a small data set obtained from zones (the zones 1, 2, 4, and 5) except the specific zone, and generates a model (second model) applicable to each zone by transfer learning based on these data sets. A method of the transfer learning is the same as Embodiment 1.

As described above, in Embodiment 3, by transferring a model generated in a specific zone in the same apparatus, it is possible to generate a model applicable to other zones. Although the number of zones is five in the example of FIG. 8, the number of zones is not limited, and transfer is possible regardless of a number of substrates loaded in the vertical furnace. When acquiring data sets in other zones, a virtual measurement technique may be used.

In addition, it may be configured that as the first model MD1, a model that simulates a substrate processing at a specific point on a substrate processed in a specific zone is generated in advance, and as the second model MD2, a model that simulates a substrate processing at an arbitrary point on a substrate processed in another zone is generated by transfer learning.

### Embodiment 4

In Embodiment 4, an application example of a single-wafer type apparatus is described.

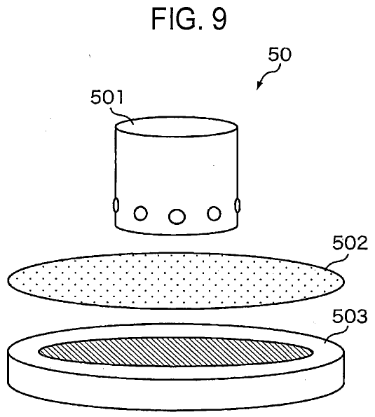

FIG. 9 is a schematic diagram illustrating a schematic configuration of a single-wafer type apparatus. A single-wafer type apparatus 50 includes a gas dispersing member 501 and a shower plate 502 as members constituting a shower head, and includes a heater 503 as a member that heats a substrate of a workpiece. The gas dispersing member 501 is a columnar member that has a closed bottom surface and includes a plurality of discharge ports discharging a gas horizontally in a side surface thereof, and evenly diffuses the gas in a gas diffusion chamber of the shower head. The shower plate 502 is provided with a plurality of gas discharge holes. The shower plate 502 discharges the gas diffused in the gas diffusion chamber into a chamber. The heater 503 heats a substrate placed in the chamber to a desired temperature.

The gas dispersing member 501 and the shower plate 502 have influence on an in-plane gas concentration distribution of the substrate, and the heater 503 has influence on an in-plane temperature distribution. Since the in-plane gas concentration distribution or the in-plane temperature distribution may be handled as offsets, a model may be transferred by performing a small number of additional experiments and using the same method as Embodiment 1. For example, it may be configured that as the first model MD1, a model that simulates a substrate processing at a specific point on the substrate is generated in advance, and as the second model MD2, a model that simulates a substrate processing at an arbitrary point on the substrate is generated by transfer learning.

As described above, in Embodiment 4, in the single-wafer type apparatus 50, by transferring a model generated at a specific point in a plane, it is possible to generate a model applicable to another point.

### Embodiment 5

In Embodiment 5, a configuration that performs a trend analysis by using a generated second model MD2 is described.

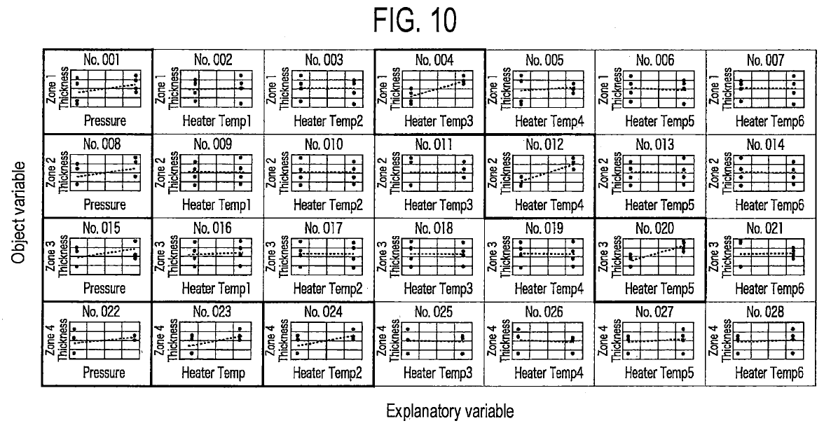

The information processing apparatus 100 according to Embodiment 5 generates data in a pseudo manner by using the generated second model MD2 to visualize a trend of an object variable with respect to an explanatory variable. FIG. 10 is a schematic diagram illustrating an analysis result of a trend analysis. When, as the second model MD2, a second model MD2 representing a relationship between a heater temperature (explanatory variable) and a film thickness (object variable) is obtained, the controller 101 of the information processing apparatus 100 changes the heater temperature in various ways and inputs them to the second model MD2 so as to calculate a film thickness at each heater temperature. Based on calculation results, the controller 101 arrays, for example, graphs showing relationships between various heater temperatures and film thicknesses, and displays the graphs on the display 105. FIG. 10 shows an example of an output.

By checking such an output example, a manager or the like may understand a trend of the film thickness with respect to the heater temperature. Further, the manager or the like may specify, for example, an element having a high relationship between an explanatory variable (adjustment knob) and an object variable, i.e., an element having a high degree of contribution, which may be used to select the adjustment knob.

### Embodiment 6

In Embodiment 6, a configuration that optimizes a process condition by using a generated second model MD2 is described.

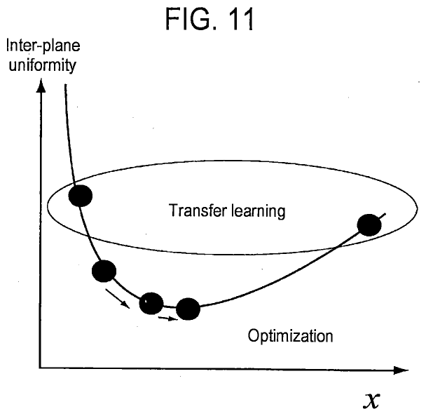

The information processing apparatus 100 according to Embodiment 6 optimizes the process condition by using the generated second model MD2. FIG. 11 is an explanatory diagram illustrating an outline of optimization. For example, when, as the second model, a model representing a relationship between a heater temperature (explanatory variable) and an inter-plane uniformity of a film forming speed (object variable) is obtained, additional experiments with different heater temperatures are performed several times to optimize the process condition. In a process of optimizing the process condition, the second model MD2 is updated and optimized. A graph shown in FIG. 11 shows a state in which by optimizing a process condition (heater temperature) of the second model MD2, the second model MD2 is optimized, and the inter-plane uniformity of the film forming speed becomes minimized.

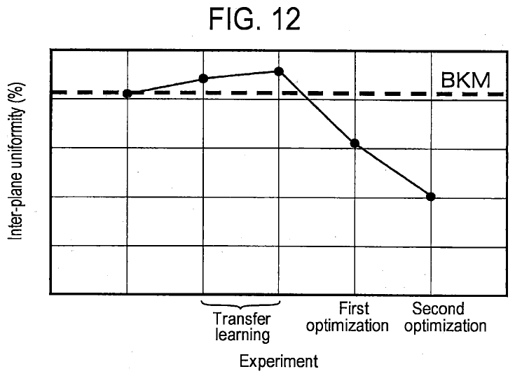

FIG. 12 is a graph illustrating an example of a verification result. In the graph, the horizontal axis represents the number of experiments, and the vertical axis represents the inter-plane uniformity of the film forming speed. The graph in FIG. 12 shows that, from the first model MD1 obtained from the first substrate processing, a model (second model MD2) comparable to a best knowledge method (BKM) is obtained by only two additional experiments (transfer learning). The BKM means a method well-known in its field, and in this example, a result that achieves an inter-plane uniformity comparable to or better than the BKM is obtained by the transfer leaning.

In addition, by optimizing the process condition with further additional experiments, the second model MD2 was optimized, and the inter-plane uniformity became about a half of the BKM.

As described above, in Embodiment 6, it is possible to optimize the process condition by using the generated second model MD2, and the second model MD2 is optimized in the process.

### Embodiment 7

In Embodiment 7, a search method of a machine specification is described.

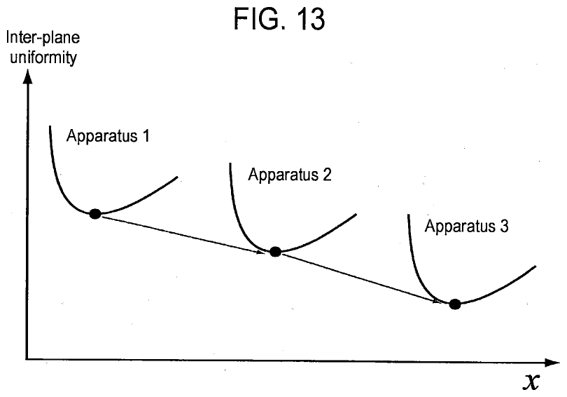

FIG. 13 is an explanatory diagram illustrating a search method of a machine specification. By comparing optimum values before and after remodeling an apparatus, using the method described in Embodiment 6, a specification provided by the apparatus may be compared and evaluated. In FIG. 13, apparatus 1 is the second substrate processing apparatus 20 before remodeling. The information processing apparatus 100 derives the optimum values of the process condition by optimizing the second model MD2, using the method described in Embodiment 6, with respect to the second substrate processing apparatus 20 before remodeling. Apparatus 2 is the second substrate processing apparatus 20 after remodeling, and apparatus 3 is the second substrate processing apparatus 20 after further remodeling the apparatus 2. The information processing apparatus 100 derives the optimum values of the process condition by optimizing the second model MD2, using the method described in Embodiment 6, with respect to each of the apparatuses (the apparatus 2 and the apparatus 3) after remodeling.

The information processing apparatus 100 may compare and evaluate a specification provided by the second substrate processing apparatus 20 based on the derived optimum values of the process condition.

### Embodiment 8

In Embodiment 8, a search method of an operation condition is described.

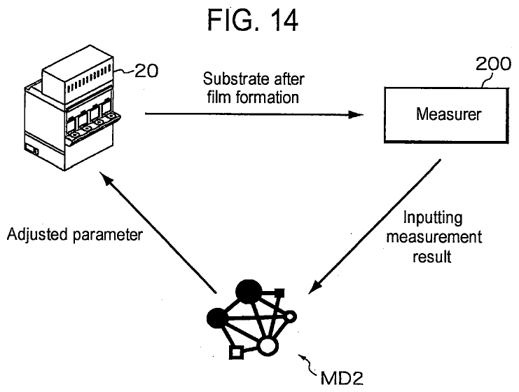

FIG. 14 is an explanatory diagram illustrating a search method of an operation condition. A substrate processing is performed in the second substrate processing apparatus 20 after the second model MD2 is generated. A measurer 200 is, for example, an apparatus that measures the film forming speed, and measures the film forming speed with respect to a plurality of substrates, thereby monitoring the inter-plane uniformity.

The information processing apparatus 100 acquires a measurement result by the measurer 200 to calculate a gap from a reference value, and derives a suitable operation condition by using the second model MD2 to reduce the gap. The information processing apparatus 100 outputs the derived operation condition to the second substrate processing apparatus 20.

The second substrate processing apparatus 20 operates under the operation condition provided from the information processing apparatus 100, so that a substrate processing having a small gap from the reference value is realized.

The embodiments disclosed herein should be considered to be exemplary and not limitative in all respects. The scope of the present disclosure is indicated by the claims rather than the above description, and it is intended that all changes within the meaning and range equivalent to the claims are included.

In addition, items described in the individual embodiments may be combined together. Independent and dependent claims described in the claims may be combined together in all combinations regardless of citing formats. Further, a format (multi-claim format) in which a claim cites other two or more claims is used in the claims, but the present disclosure is not limited thereto. A format in which a multi-claim (multi-multi claim) cites at least one other multi-claim may be used.

According to the present disclosure, it is possible to generate a model by using a small data set.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A non-transitory computer-readable recording medium storing a computer program that causes a computer to perform:
acquiring a first model that simulates a behavior of a first substrate processing;
setting a range of variables that are able to approximate the acquired first model by a regression equation;
deriving the regression equation that approximates the first model within the set range;
acquiring observation data on a second substrate processing different from the first substrate processing; and
generating a second model that simulates a behavior of the second substrate processing by adjusting coefficients in the regression equation based on the acquired observation data.

2. The recording medium of claim 1, wherein the regression equation is a multiple linear regression equation that includes intercepts and partial regression coefficients as the coefficients, and
wherein the computer program causes the computer to perform adjusting the coefficients in the multiple linear regression equation by imposing a penalty for a difference between a partial regression coefficient before adjustment and a partial regression coefficient after adjustment so as to reproduce the observation data.

3. The recording medium of claim 2, wherein the computer program causes the computer to perform adjusting the coefficients in the multiple linear regression equation by imposing a penalty according to a distance between two arbitrary points in a substrate plane of a workpiece to a partial regression coefficient to be adjusted.

4. The recording medium of claim 3, wherein the computer program causes the computer to perform adjusting a coefficient β_{T} in the multiple linear regression equation based on Equation 1:
$${β}_{T} = arg min ( {\sum }_{i}^{n} {‖ {y}_{T} - {β}_{i} x ‖}^{2} + {λ}_{1} {‖ {β}_{i}^{′} - {β}_{s}^{′} ‖}^{2} + {λ}_{2} {\sum }_{j \neq i}^{n - 1} \frac{1}{{r}^{2}} {‖ {β}_{i}^{′} - {β}_{j}^{′} ‖}^{2} ) \qquad [ Equation 1 ]$$
β_{T}: a regression coefficient in a model of a transfer destination
β_{S}: a regression coefficient in a model of a transfer source
x: input data of the multiple linear regression equation
y_{T}: output data of the multiple linear regression equation
n: a number of observation points
βᵢ: a regression coefficient (including an intercept)
β′: a regression coefficient (including no intercept)
r: a distance between observation points
λ₁, λ₂: parameters for adjustment.

5. The recording medium of claim 1, wherein the first substrate processing is a substrate processing in an experiment apparatus,
wherein the second substrate processing is a substrate processing in a mass production apparatus, and
wherein the computer program causes the computer to perform generating a second model that simulates a behavior of the substrate processing in the mass production apparatus based on a first model that simulates a behavior of the substrate processing in the experiment apparatus.

6. The recording medium of claim 1, wherein the first substrate processing is a substrate processing in a first zone in a vertical furnace including a plurality of zones,
wherein the second substrate processing is a substrate processing in a second zone different from the first zone, and
wherein the computer program causes the computer to perform generating a second model that simulates a behavior of the substrate processing in the second zone based on a first model that simulates a behavior of the substrate processing in the first zone.

7. The recording medium of claim 6, wherein the computer program causes the computer to perform generating, as the second model, a second model that simulates a behavior of a substrate processing at an arbitrary point on a substrate processed in the second zone based on a first model that simulates a behavior of a substrate processing at a specific point on a substrate processed in the first zone.

8. The recording medium of claim 1, wherein the first substrate processing and the second substrate processing are substrate processings in a single-wafer type apparatus, and
wherein the computer program causes the computer to perform generating a second model that simulates a behavior of a substrate processing at an arbitrary point on a substrate processed in the single-wafer type apparatus based on a first model that simulates a behavior of a substrate processing at a specific point on the substrate.

9. The recording medium of claim 1, wherein the computer program causes the computer to perform performing a trend analysis in the second substrate processing based on the generated second model.

10. The recording medium of claim 1, wherein the computer program causes the computer to perform optimizing a process condition in the second substrate processing based on the generated second model.

11. The recording medium of claim 1, wherein the computer program causes the computer to perform searching for a machine specification of a substrate processing apparatus, which performs the second substrate processing, based on the generated second model.

12. The recording medium of claim 1, wherein the computer program causes the computer to perform searching for an operation condition of a substrate processing apparatus, which performs the second substrate processing, based on the generated second model.

13. The recording medium of claim 4, wherein the computer program causes the computer to perform:
receiving a change of the parameters for adjustment in an operation expression of Equation 1;
updating the multiple linear regression equation according to the change of the parameters for adjustment; and
displaying together the observation data within the range and a multiple linear regression equation after updating, which approximates the observation data within the range.

14. An information processing apparatus, comprising:
a first acquirer configured to acquire a first model that simulates a behavior of a first substrate processing;
a setter configured to set a range of variables that are able to approximate the acquired first model by a regression equation;
a deriver configured to derive the regression equation that approximates the first model within the set range;
a second acquirer configured to acquire observation data on a second substrate processing different from the first substrate processing; and
a generator configured to generate a second model that simulates a behavior of the second substrate processing by adjusting coefficients in the regression equation based on the acquired observation data.

15. An information processing method for causing a computer to perform:
acquiring a first model that simulates a behavior of a first substrate processing;
setting a range of variables that are able to approximate the acquired first model by a regression equation;
deriving the regression equation that approximates the first model within the set range;
acquiring observation data on a second substrate processing different from the first substrate processing; and
generating a second model that simulates a behavior of the second substrate processing by adjusting coefficients in the regression equation based on the acquired observation data.
